(19) United States
(12) Patent Application Publication
(10) Pub. No.: US 2009/0224804 A1
(43) Pub. Date: Sep. 10, 2009

(54) DETECTING CIRCUIT AND ELECTRONIC APPARATUS USING DETECTING CIRCUIT

(75) Inventor: Ippei Noda, Osaka (JP)

Correspondence Address: COOPER & DUNHAM, LLP, 30 Rockefeller Plaza, 20th Floor, NEW YORK, NY, 10112, US

(73) Assignee: Ricoh Company, Ltd., Tokyo (JP)

(21) Appl. No.: 12/440,829

(22) PCT Filed: Jul. 16, 2008
(86) PCT No.: PCT/JP2008/063229

§ 371 Date: Mar. 11, 2009

(30) Foreign Application Priority Data
Aug. 7, 2007 (JP) 2007-205113

(51) Int. Cl. G01R 19/00; H03K 5/00; H03K 17/14

(52) U.S. Cl. 327/53; 327/50; 327/512

(57) ABSTRACT

A detecting circuit is disclosed. In the detecting circuit, when an input detection voltage Vsns which is obtained by dividing an input voltage Vin by resistors is equal to a reference voltage Vref or more and a temperature detection voltage Tsns is equal to the reference voltage Vref or more due to a low temperature, a detection signal SNS from a comparator becomes a high level. In addition, when the input detection voltage Vsns is less than the reference voltage Vref and/or the temperature detection voltage Tsns is less than the reference voltage Vref due to a high temperature, the detection signal SNS from the comparator becomes a low level.

### TECHNICAL FIELD

The present invention generally relates to a detecting circuit which detects an input voltage and an ambient temperature, generates a detection signal signifying the detected results, and outputs the generated detection signal; and an electronic apparatus using the detecting circuit.

### BACKGROUND ART

Generally, an electronic apparatus is started up when an input voltage rises to a predetermined voltage. However, in some cases, conditions are added other than the input voltage when the electronic apparatus is started up. Especially, since a high temperature may damage a semiconductor device in the electronic apparatus, when the ambient temperature is a predetermined temperature or more, it is determined that the electronic apparatus is not to be started up or operations of the electronic apparatus are to be changed.

FIG. 7 is a circuit diagram showing a conventional detecting circuit.

As shown in FIG. 7, a detecting circuit 100 provides an input voltage detecting circuit 101 which detects an input voltage Vin, a temperature detecting circuit 102 which detects an ambient temperature, and an AND circuit 103 which generates a detection signal SNS signifying detected results of the input voltage detecting circuit 101 and the temperature detecting circuit 102 and outputs the generated detection signal SNS.

The input voltage detecting circuit 101 provides a first reference voltage generating circuit 111 which generates a predetermined reference voltage Vr1 and outputs the generated reference voltage Vr1, resistors R111 and R112, and a comparator (CMP) 112. The temperature detecting circuit 102 provides a second reference voltage generating circuit 121 which generates a predetermined reference voltage Vr2 and outputs the generated reference voltage Vr2, a constant current source 122 which generates a predetermined constant current ia and outputs the generated constant current ia, a PNP transistor Qa, and a comparator (CMP) 123.

When the input voltage Vin rises and a voltage at the connection point of the resistor R111 with the R112 becomes the predetermined reference voltage Vr1 or more, the CMP 112 outputs a high level signal, and when an ambient temperature is a predetermined value or less, a voltage between the emitter and the base of the PNP transistor Qa becomes the predetermined reference voltage Vr2 or more, the CMP 123 outputs a high level signal. When both of the CMPs 112 and 123 output the corresponding high level signals, the detection signal SNS to be output from the AND circuit 103 becomes a high level signal.

Patent Document 1 is different from the present invention. However, Patent Document 1 discloses an electronic apparatus having a temperature detecting circuit and a heat preventing circuit. In the electronic apparatus, a reference voltage generating circuit is formed by using MOS transistor technology, and the temperature detecting circuit and the heat preventing circuit are formed so that the corresponding occupying area of the circuits are small and the power consumption of the circuits is low.

[Patent Document 1] Japanese Laid-Open Patent Application No. 2005-122753

However, in the detecting circuit 100 shown in FIG. 7, since each of the input voltage detecting circuit 101 and the temperature detecting circuit 102 must include a reference voltage generating circuit and a comparator, the area of an IC chip of the detecting circuit 100 is great and the power consumption is high.

### DISCLOSURE OF THE INVENTION

In an embodiment of the present invention, there is provided a detecting circuit and an electronic apparatus using the detecting circuit in which the area of an IC chip of the detecting circuit is small and the power consumption is low.

To achieve one or more of these and other advantages, according to one aspect of the present invention, there is provided a detecting circuit which detects whether plural conditions are satisfied, generates a predetermined detection signal signifying the detected result, and outputs the generated detection signal. The detecting circuit includes a comparator having one inverting input terminal and plural non-inverting input terminals. A predetermined reference voltage is input to the inverting input terminal of the comparator, corresponding voltages for detecting the plural conditions are input to the corresponding non-inverting input terminals of the comparator, and the comparator generates the predetermined detection signal and outputs the generated detection signal when the plural conditions are satisfied.

According to another aspect of the present invention, there is provided a detecting circuit which detects whether plural conditions are satisfied, generates a predetermined detection signal signifying the detected result, and outputs the generated detection signal. The detecting circuit includes a comparator having one non-inverting input terminal and plural inverting input terminals. A predetermined reference voltage is input to the non-inverting input terminal of the comparator, corresponding voltages for detecting the plural conditions are input to the corresponding inverting input terminals of the comparator, and the comparator generates the predetermined detection signal and outputs the generated detection signal when the plural conditions are satisfied.

According to another aspect of the present invention, there is provided an electronic apparatus. The electronic apparatus includes a detecting circuit which detects whether plural conditions are satisfied, generates a predetermined detection signal signifying the detected result, and outputs the generated detection signal; and one or more functional circuits having corresponding functions which circuits are operated based on the detection signal. The detecting circuit includes a comparator having one inverting input terminal and plural non-inverting input terminals. A predetermined reference voltage is input to the inverting input terminal of the comparator, corresponding voltages for detecting the plural conditions are input to the corresponding non-inverting input terminals of the comparator, and the comparator generates the predetermined detection signal and outputs the generated detection signal when the plural conditions are satisfied.

According to another aspect of the present invention, there is provided an electronic apparatus. The electronic apparatus includes a detecting circuit which detects whether plural conditions are satisfied, generates a predetermined detection signal signifying the detected result, and outputs the generated detection signal; and one or more functional circuits having corresponding functions which circuits are operated based on the detection signal. The detecting circuit includes a comparator having one non-inverting input terminal and plural inverting input terminals, a predetermined reference voltage is input to the non-inverting input terminal of the comparator, corresponding voltages for detecting the plural conditions are input to the corresponding inverting input terminals of the comparator, and the comparator generates the predetermined detection signal and outputs the generated detection signal when the plural conditions are satisfied.

According to an embodiment of the present invention, a detecting circuit detects whether plural conditions are satisfied, generates a predetermined detection signal signifying the detected result, and outputs the generated detection signal. The detecting circuit includes a comparator having plural input terminals. When the detecting circuit detects, for example, an input voltage and an ambient temperature as the plural conditions, the detecting circuit detects whether predetermined conditions between the ambient temperature and the input voltage are satisfied by using the plural input terminals of the comparator. That is, the detecting circuit detects whether conditions that the input voltage is the predetermined voltage or more and the ambient temperature is the predetermined temperature or less are satisfied. Therefore, the circuit structure of the detecting circuit can be simplified, the area of the IC chip of the detecting circuit can be small, and the power consumption of the detecting circuit can be lowered.

The features and advantages of the present invention will become more apparent from the following detailed description of a preferred embodiment given with reference to the accompanying drawings.

### BRIEF DESCRIPTION OF THE DRAWINGS

FIG. 1 is a circuit diagram showing a detecting circuit according to a first embodiment of the present invention;

FIG. 2 is a circuit diagram showing a CMP shown in FIG. 1;

FIG. 3 is a circuit diagram showing a first example of an electronic apparatus using the detecting circuit shown in FIG. 1;

FIG. 4 is a circuit diagram showing a second example of an electronic apparatus using the detecting circuit shown in FIG. 1;

FIG. 5 is a circuit diagram showing a detecting circuit according to a second embodiment of the present invention;

FIG. 6 is a circuit diagram showing a CMP shown in FIG. 5; and

FIG. 7 is a circuit diagram showing a conventional detecting circuit.

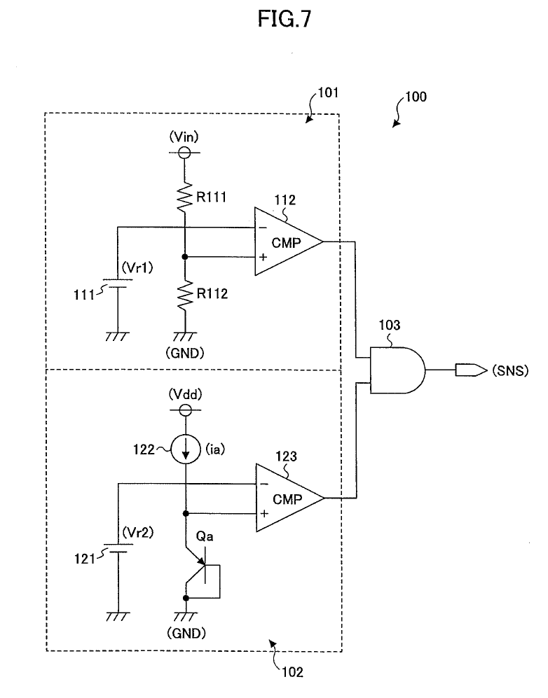

### BEST MODE FOR CARRYING OUT THE INVENTION

Referring to the drawings, embodiments of the present invention are described in detail.

### First Embodiment

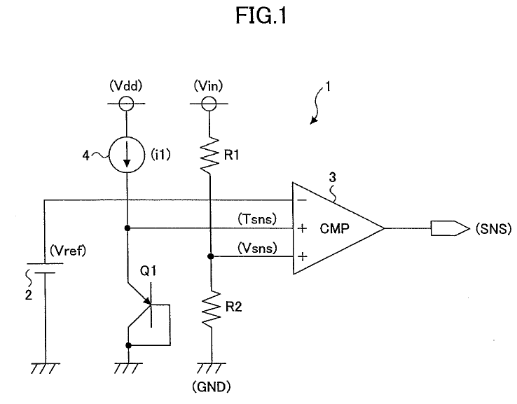

FIG. 1 is a circuit diagram showing a detecting circuit according to a first embodiment of the present invention.

A detecting circuit 1 detects an input voltage Vin and an ambient temperature T (not shown), and outputs a predetermined detection signal SNS when the input voltage Vin is a predetermined voltage V1 (not shown) or more and the ambient temperature T is a predetermined temperature T1 (not shown) or less.

As shown in FIG. 1, the detecting circuit 1 includes a reference voltage generating circuit 2 which generates a predetermined reference voltage Vref and outputs the generated reference voltage Vref, a comparator (CMP) 3 having two non-inverting input terminals and an inverting input terminal (three input terminals), a constant current source 4 which generates a predetermined constant current i1 and outputs the generated constant current i1, a PNP transistor Q1, and resistors R1 and R2.

The constant current source 4 and the PNP transistor Q1 form a temperature detection voltage generating circuit, and the resistors R1 and R2 form an input detection voltage generating circuit (voltage dividing circuit). In addition, the predetermined voltage V1 is a first predetermined value, and the predetermined temperature T1 is a second predetermined value.

The constant current source 4 is connected between a power source voltage Vdd and the emitter of the PNP transistor Q1, the collector and the base of the PNP transistor Q1 are connected to ground potential, and the emitter of the PNP transistor Q1 is connected to one of the non-inverting input terminals of the CMP 3. That is, the PNP transistor Q1 forms a bipolar diode by connecting the base to the collector.

In addition, the resistors R1 and R2 are connected in series between the input voltage Vin and ground potential (GND), and the connection point of the resistor R1 with the resistor R2 is connected to the other of the non-inverting input terminals of the CMP 3. The reference voltage Vref is input to the inverting input terminal of the CMP 3, and the detection signal SNS is output from an output terminal of the CMP 3.

The CMP 3 outputs a detection signal SNS of a high level when voltages Tsns and Vsns input to the non-inverting input terminals of the CMP 3 become equal to a voltage input to the inverting input terminal of the CMP 3 or more. In addition, the CMP 3 outputs a detection signal SNS of a low level when at least one of the voltages Tsns and Vsns input to the non-inverting input terminals of the CMP 3 becomes less than the voltage input to the inverting input terminal of the CMP 3.

The predetermined constant current i1 is supplied to the PNP transistor Q1 from the constant current source 4, and a voltage between the emitter and the base of the PNP transistor Q1 is a function of an ambient temperature. That is, in the PNP transistor Q1, when the ambient temperature rises, the voltage between the emitter and the base falls, and when the ambient temperature falls, the voltage between the emitter and the base rises.

Therefore, the voltage between the emitter and the base of the PNP transistor Q1 becomes the voltage Tsns (temperature detection voltage), and the reference voltage Vref or the constant current i1 is determined so that the temperature detection voltage Tsns becomes equal to the reference voltage Vref at a desired detection temperature. The voltage between the emitter and the base of the PNP transistor Q1 corresponds to a forward voltage of the bipolar diode formed of the PNP transistor Q1.

In addition, when (1) the input voltage Vin is input, (2) the voltage Vsns (input detection voltage) which is a divided voltage in which the input voltage Vin is divided by the resistors R1 and R2 becomes equal to the reference voltage Vref or more, and (3) the temperature detection voltage Tsns is equal to the reference voltage Vref or more due to a low detection temperature, the detection signal SNS output from the CMP 3 becomes a high level. Further, when (1) the input voltage Vin is input, (2) the input detection voltage Vsns is less than the reference voltage Vref, and/or (3) the temperature detection voltage Tsns is less than the reference voltage Vref due to a high detection temperature, the detection signal SNS from the CMP 3 becomes a low level.

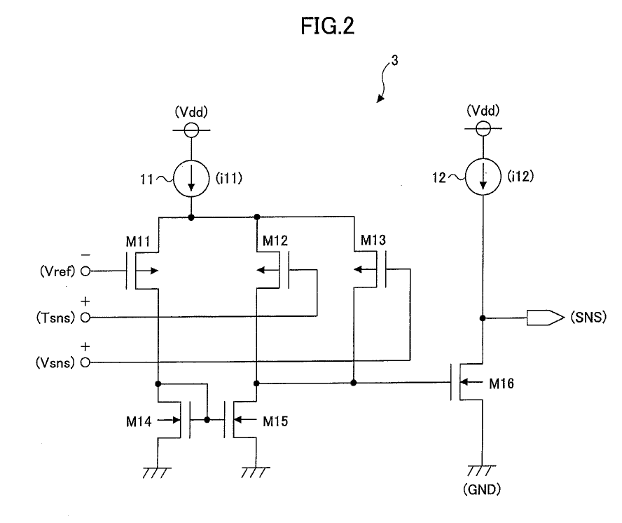

FIG. 2 is a circuit diagram showing the CMP 3 shown in FIG. 1.

As shown in FIG. 2, the CMP 3 includes PMOS transistors M11, M12, and M13 which are input transistors, and NMOS transistors M14, M15, and M16, a constant current source 11 which generates a constant current i11 and outputs the generated constant current i11, and a constant current source 12 which generates a constant current i12 and outputs the generated constant current i12.

The PMOS transistors M11, M12, and M13, the NMOS transistors M14 and M15, and the constant current source 11 form a differential amplifier circuit. The PMOS transistor M11 is a first input transistor, the PMOS transistor M12 is a second input transistor, and the PMOS transistor M13 is a third input transistor.

The constant current source 11 is connected between the sources of the PMOS transistors M11 through M13 and the power source voltage Vdd. The gate (control electrode) of the PMOS transistor M11 is the inverting input terminal of the CMP 3, and the reference voltage Vref is input to the gate. The gate (control electrode) of the PMOS transistor M12 is one of the non-inverting input terminals of the CMP 3, and the temperature detection voltage Tsns is input to the gate. The gate (control electrode) of the PMOS transistor M13 is the other of the non-inverting input terminals of the CMP 3, and the input detection voltage Vsns is input to the gate.

The NMOS transistors M14 and M15 which are a load on the PMOS transistors M11 through M13 form a current mirror circuit. The sources of the NMOS transistors M14 and M15 are connected to ground potential, and the gates of the NMOS transistors M14 and M15 are connected to the drain of the NMOS transistor M14.

The drain of the PMOS transistor M11 is connected to the drain of the NMOS transistor M14, and the drains of the PMOS transistors M12 and M13 are connected to the drain of the NMOS transistor M15 and the gate of the NMOS transistor M16. The constant current source 12 is connected between the power source voltage Vdd and the drain of the NMOS transistor M16, and the source of the NMOS transistor M16 is connected to ground potential (GND). The detection signal SNS is output from the connection point of the constant current source 12 with the drain of the NMOS transistor M16.

Next, operations of the CMP 3 are described.

When at least one of the gate voltages (Tsns and Vsns) of the corresponding PMOS transistors M12 and M13 is less than the reference voltage Vref, the drain current of the PMOS transistor whose gate voltage is less than the reference voltage Vref becomes greater than the drain current of the PMOS transistor M11. Therefore, the drain voltage of the NMOS transistor M15 rises, the gate voltage of the NMOS transistor M16 rises, the NMOS transistor M16 becomes ON, and the detection signal SNS becomes a low level.

When both of the gate voltages (Tsns and Vsns) of the PMOS transistors M12 and M13 are equal to the reference voltage Vref or more, the drain current to be supplied to the NMOS transistor M15 becomes less than the drain current to be supplied to the NMOS transistor M14 by the PMOS transistor M11. Therefore, the drain voltage of the NMOS transistor M15 falls, the NMOS transistor M16 becomes OFF, and the detection signal SNS becomes a high level.

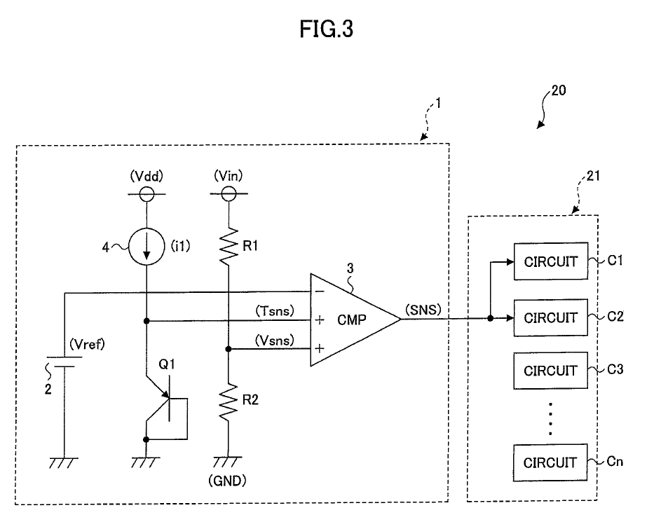

Next, referring to FIG. 3, a first example of an electronic apparatus 20 using the detecting circuit 1 shown in FIG. 1 is described.

FIG. 3 is a circuit diagram showing the first example of the electronic apparatus 20 using the detecting circuit 1 shown in FIG. 1.

As shown in FIG. 3, the electronic apparatus 20 includes the detecting circuit 1 and a circuit block 21. The circuit block 21 includes plural circuits C1 through Cn (n is an integer of two or more). The circuits C1 through Cn have corresponding functions.

In FIG. 3, for example, the circuits C1 and C2 cannot be operated at a high temperature, and the detection signal SNS from the detecting circuit 1 is input to the circuits C1 and C2. When the detection signal SNS is a low level, the circuits C1 and C2 stop the operations, and when the detection signal SNS is a high level, the circuits C1 and C2 are operated.

When the circuits C1 and C2 have corresponding problems at a high ambient temperature, the detection signal SNS is input to the circuits C1 and C2, and right after the input voltage Vin is input to the detecting circuit 1, the operations of the circuits C1 and C2 are stopped at the high temperature. Therefore, the problems at the high temperature can be prevented in the circuits C1 and C2.

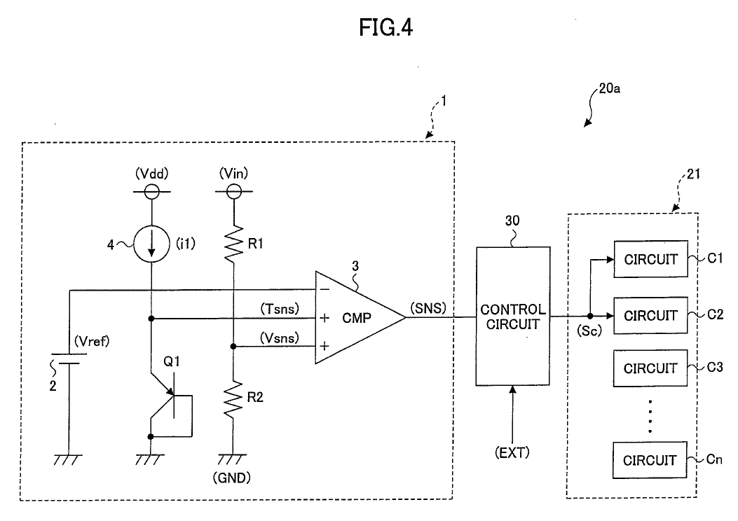

Next, referring to FIG. 4, a second example of an electronic apparatus 20a using the detecting circuit 1 shown in FIG. 1 is described.

FIG. 4 is a circuit diagram showing the second example of the electronic apparatus 20a using the detecting circuit 1 shown in FIG. 1.

As shown in FIG. 4, when the electronic apparatus 20a shown in FIG. 4 is compared with the electronic apparatus 20 shown in FIG. 3, the electronic apparatus 20a further includes a control circuit 30. As shown in FIG. 4, in addition to the detection signal SNS from the detecting circuit 1, an external input signal EXT is input to the control circuit 30 from an external device (not shown). In addition, an output signal Sc from the control circuit 30 is input to the circuits C1 and C2.

For example, when the detection signal SNS is a high level, the output signal Sc from the control circuit 30 is changed corresponding to the level of the external input signal EXT, and when the detection signal SNS is a low level, the output signal Sc from the control circuit 30 becomes a low level regardless of the level of the external input signal EXT.

A relationship among the signals SNS, EXT, and Sc; and operating statuses of the circuits C1 and C2 is shown in TABLE 1. In TABLE 1, H signifies a high level and L signifies a low level.

TABLE 1

| SNS | EXT | Sc | CIRCUITS C1 AND C2 |
|---|---|---|---|
| H | L | L | NON-OPERATING STATUS |
| H | H | H | OPERATING STATUS |
| L | L | L | NON-OPERATING STATUS |
| L | H | L | NON-OPERATING STATUS |

As described above, according to the first embodiment of the present invention, the detecting circuit 1 includes the CMP 3 having the three input terminals, and detects whether predetermined conditions between the ambient temperature T and the input voltage Vin are satisfied. That is, the detecting circuit 1 detects whether conditions that the input voltage Vin is equal to the predetermined voltage V1 or more and the ambient temperature T is equal to the predetermined temperature T1 or less are satisfied. Therefore, the circuit structure of the detecting circuit 1 can be simplified, the area of the IC chip of the detecting circuit 1 can be small, and the power consumption of the detecting circuit 1 can be lowered.

### Second Embodiment

Next, referring to the drawings, a second embodiment of the present invention is described. In the second embodiment of the present invention, when an element is similar to or the same as that in the first embodiment of the present invention, the same reference number as that in the first embodiment of the present invention is used for the element, and the same description as that in the first embodiment of the present invention is omitted.

In the first embodiment of the present invention, the CMP 3 is used which CMP 3 has the two non-inverting input terminals and the one inverting input terminal. In the second embodiment of the present invention, a CMP 3a of a detecting circuit 1a includes two inverting input terminals and one non-inverting input terminal.

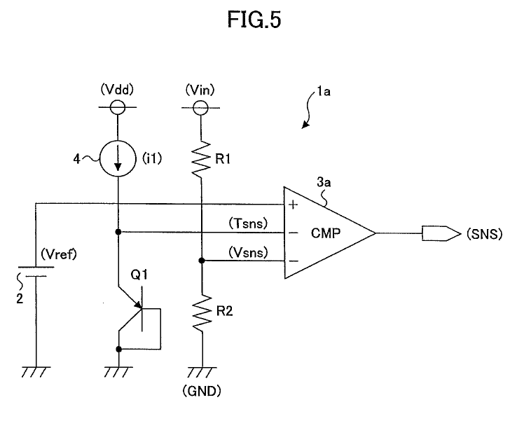

FIG. 5 is a circuit diagram showing the detecting circuit 1a according to the second embodiment of the present invention.

In FIG. 5, the detecting circuit 1a detects an input voltage Vin and an ambient temperature T (not shown), and when the input voltage Vin is a predetermined voltage V1 (not shown) or more and the ambient temperature T is a predetermined temperature T1 (not shown) or less, the detecting circuit 1a generates a predetermined detection signal SNS and outputs the generated detection signal SNS.

The detecting circuit 1a includes a reference voltage generating circuit 2, the comparator (CMP) 3a having the two inverting input terminals and the one non-inverting input terminal, a constant current source 4, a PNP transistor Q1, and resistors R1 and R2.

In the CMP 3a, a reference voltage Vref is input to the non-inverting input terminal, a temperature detection voltage Tsns is input to one of the inverting input terminals, and an input detection voltage Vsns is input to the other of the inverting input terminals.

The CMP 3a outputs a detection signal SNS of a low level when the temperature detection voltage Tsns and the input detection voltage Vsns become equal to the reference voltage Vref or more. In addition, the CMP 3a outputs a detection signal SNS of a high level when at least one of the temperature detection voltage Tsns and the input detection voltage Vsns is less than the reference voltage Vref.

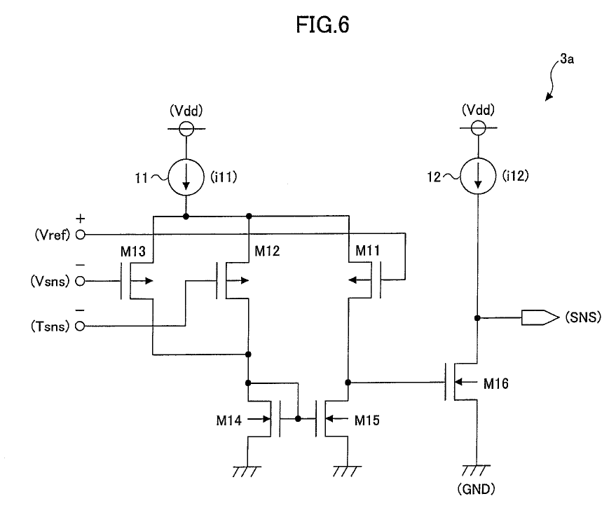

FIG. 6 is a circuit diagram showing the CMP 3a shown in FIG. 5.

As shown in FIGS. 2 and 6, the connections between the PMOS transistors M11 through M13 and the NMOS transistors M14 and M15 are different between the CMPs 3 and 3a.

That is, in FIG. 6, the drain of the PMOS transistor M11 and the drain of the NMOS transistor M15 are connected to the gate of the NMOS transistor M16. The drain of the PMOS transistor M12 and the drain of the PMOS transistor M13 are connected to the drain of the NMOS transistor M14. That is, the gate (control electrode) of the PMOS transistor M11 is the non-inverting input terminal of the CMP 3a, and the gates (control electrodes) of the PMOS transistors M12 and M13 are the corresponding inverting input terminals of the CMP 3a.

When at least one of the gate voltages (Tsns and Vsns) of the PMOS transistors M12 and M13 is less than the reference voltage Vref, the drain current of the PMOS transistor whose gate voltage is less than the reference voltage Vref becomes greater than the drain current of the PMOS transistor M11. Consequently, the drain voltage of the NMOS transistor M14 rises and the drain voltage of the NMOS transistor M15 falls. Therefore, the gate voltage of the NMOS transistor M16 falls and the NMOS transistor M16 becomes OFF, and the detection signal SNS becomes a high level.

In addition, when the gate voltages (Tsns and Vsns) of the PMOS transistors M12 and M13 become equal to the reference voltage Vref or more, the drain current to be supplied to the NMOS transistor 14 is less than the drain current to be supplied to the NMOS transistor M15 from the PMOS transistor M11. Consequently, the drain voltage of the NMOS transistor M14 falls and the drain voltage of the NMOS transistor M15 rises. Therefore, the NMOS transistor M16 becomes ON, and the detection signal SNS becomes a low level.

In the first example of the electronic apparatus 20 shown in FIG. 3, when the detecting circuit 1a shown in FIG. 5 is used, the circuits C1 and C2 are in corresponding operating statuses when the detection signal SNS is a low level, and the circuits C1 and C2 are in corresponding non-operating statuses when the detection signal SNS is a high level.

In addition, in the second example of the electronic apparatus 20a shown in FIG. 4, in a case where the detecting circuit 1a shown in FIG. 5 is used, when the detection signal SNS is a low level, the output signal Sc from the control circuit 30 is changed corresponding to the level of the external input signal EXT, and when the detection signal SNS is a high level, the output signal Sc from the control circuit 30 becomes a high level regardless of the level of the external input signal EXT. That is, when the detection signal SNS is the low level and the external input signal is the low level, the output signal Sc becomes the low level, then the circuits C1 and C2 are operated.

As described above, according to the second embodiment of the present invention, the detecting circuit 1a includes the CMP 3a having the three input terminals, and detects whether predetermined conditions between the ambient temperature T and the input voltage Vin are satisfied. That is, the detecting circuit 1a detects whether conditions that the input voltage Vin is equal to the predetermined voltage V1 or more and the ambient temperature T is equal to the predetermined temperature T1 or less are satisfied. Therefore, similar to the detecting circuit 1 in the first embodiment of the present invention, the circuit structure of the detecting circuit 1a can be simplified, the area of the IC chip of the detecting circuit 1a can be small, and the power consumption of the detecting circuit 1a can be lowered.

In the first and second embodiments of the present invention, the detecting circuit 1 (1a) detects whether the two conditions in which the input voltage Vin is equal to the predetermined voltage V1 or more and the ambient temperature T is equal to the predetermined temperature T1 or less are satisfied. Therefore, the CMP 3 (3a) has the three input terminals.

However, in the embodiments of the present invention, the number of the conditions is not limited to two, and can be three or more. In a case where the number of the conditions is “m” (m is an integer three or more), when the number of the non-inverting or inverting input terminals of a CMP in a detecting circuit is determined to be “m”, the detecting circuit can detect whether the “m” conditions are satisfied.

In addition, in the first and second embodiments of the present invention, when the power source voltage Vdd is detected, the input voltage Vin is the power source voltage Vdd. In addition, the bipolar diode is formed by connecting the base and the collector of the PNP transistor Q1. However, a bipolar diode can be used instead of forming the bipolar diode with the PNP transistor Q1.

Further, the present invention is not limited to the embodiments, but various variations and modifications may be made without departing from the scope of the present invention.

The present invention is based on Japanese Priority Patent Application No. 2007-205113 filed on Aug. 7, 2007, with the Japanese Patent Office, the entire contents of which are hereby incorporated herein by reference.

1. A detecting circuit which detects whether a plurality of conditions are satisfied, generates a predetermined detection signal signifying the detected result, and outputs the generated detection signal, comprising:
a comparator having one inverting input terminal and a plurality of non-inverting input terminals; wherein
a predetermined reference voltage is input to the inverting input terminal of the comparator, and corresponding voltages for detecting the plural conditions are input to the corresponding non-inverting input terminals of the comparator; and
the comparator generates the predetermined detection signal and outputs the generated detection signal when the plural conditions are satisfied.

2. The detecting circuit as claimed in claim 1, wherein:
when an input voltage and an ambient temperature are detected as the plural conditions, the predetermined detection signal signifying the detected result is generated, and the generated detection signal is output;
the comparator includes one inverting input terminal and two non-inverting input terminals;
the predetermined reference voltage is input to the inverting input terminal;
an input detection voltage proportional to the input voltage is input to one of the two non-inverting input terminals;
a temperature detection voltage corresponding to the ambient temperature is input to the other of the two non-inverting input terminal; and
when the input voltage is a first predetermined value or more and the ambient temperature is a second predetermined value or less,
the comparator generates the predetermined detection signal and outputs the generated detection signal.

3. The detecting circuit as claimed in claim 2, wherein:
the comparator includes a differential amplifier circuit; and the differential amplifier circuit includes
a first input transistor whose control electrode is the inverting input terminal;
a second input transistor whose control electrode is one of the non-inverting input terminals;
a third input transistor whose control electrode is the other of the non-inverting input terminals;
a constant current source which supplies a predetermined constant current to the first through third input transistors; and
a current mirror circuit which is a load on the first through third input transistors; wherein
the current mirror circuit controls so that a current proportional to a current flowing into the first input transistor flows into the second and third input transistors; and
a connection point of the second and third input transistors with the current mirror circuit is an output terminal of the differential amplifier circuit.

4. A detecting circuit which detects whether a plurality of conditions are satisfied, generates a predetermined detection signal signifying the detected result, and outputs the generated detection signal, comprising:
a comparator having one non-inverting input terminal and a plurality of inverting input terminals; wherein
a predetermined reference voltage is input to the non-inverting input terminal of the comparator, and corresponding voltages for detecting the plural conditions are input to the corresponding inverting input terminals of the comparator; and
the comparator generates the predetermined detection signal and outputs the generated detection signal when the plural conditions are satisfied.

5. The detecting circuit as claimed in claim 4, wherein:
when an input voltage and an ambient temperature are detected as the plural conditions, the predetermined detection signal signifying the detected result is generated, and the generated detection signal is output;
the comparator includes one non-inverting input terminal and two inverting input terminals;
the predetermined reference voltage is input to the non-inverting input terminal;
an input detection voltage proportional to the input voltage is input to one of the two inverting input terminals;
a temperature detection voltage corresponding to the ambient temperature is input to the other of the two inverting input terminal; and
when the input voltage is a first predetermined value or more and the ambient temperature is a second predetermined value or less,
the comparator generates the predetermined detection signal and outputs the generated detection signal.

6. The detecting circuit as claimed in claim 5, wherein:
the comparator includes a differential amplifier circuit; and the differential amplifier circuit includes
a first input transistor whose control electrode is the non-inverting input terminal;
a second input transistor whose control electrode is one of the inverting input terminals;
a third input transistor whose control electrode is the other of the inverting input terminals;
a constant current source which supplies a predetermined constant current to the first through third input transistors; and
a current mirror circuit which is a load on the first through third input transistors; wherein
the current mirror circuit controls so that a current proportional to the sum of currents flowing into the first and second input transistors flows into the third input transistor; and
a connection point of the first input transistor with the current mirror circuit is an output terminal of the differential amplifier circuit.

7. The detecting circuit as claimed in claim 2, further comprising:
an input detection voltage generating circuit which generates the input detection voltage by dividing the input voltage with a predetermined dividing ratio; and
a temperature detection voltage generating circuit which detects the ambient temperature, generates the temperature detection voltage corresponding to the detected ambient temperature, and outputs the generated temperature detection voltage.

8. The detecting circuit as claimed in claim 5, further comprising:
an input detection voltage generating circuit which generates the input detection voltage by dividing the input voltage with a predetermined dividing ratio; and
a temperature detection voltage generating circuit which detects the ambient temperature, generates the temperature detection voltage corresponding to the detected ambient temperature, and outputs the generated temperature detection voltage.

9. The detecting circuit as claimed in claim 7, wherein:
the temperature detection voltage generating circuit includes
a constant current source which generates a predetermined constant current and outputs the generated constant current; and
a bipolar diode to which the constant current is supplied from the constant current source; wherein
the forward voltage of the bipolar diode is the temperature detection voltage.

10. The detecting circuit as claimed in claim 8, wherein:
the temperature detection voltage generating circuit includes
a constant current source which generates a predetermined constant current and outputs the generated constant current; and
a bipolar diode to which the constant current is supplied from the constant current source; wherein
the forward voltage of the bipolar diode is the temperature detection voltage.

11. An electronic apparatus, comprising:
a detecting circuit which detects whether a plurality of conditions are satisfied, generates a predetermined detection signal signifying the detected result, and outputs the generated detection signal; and
one or more functional circuits having corresponding functions which circuits are operated based on the detection signal; wherein
the detecting circuit includes
a comparator having one inverting input terminal and a plurality of non-inverting input terminals; wherein
a predetermined reference voltage is input to the inverting input terminal of the comparator, and corresponding voltages for detecting the plural conditions are input to the corresponding non-inverting input terminals of the comparator; and
the comparator generates the predetermined detection signal and outputs the generated detection signal when the plural conditions are satisfied.

12. The electronic apparatus as claimed in claim 11, wherein:
when an input voltage and an ambient temperature are detected as the plural conditions, the predetermined detection signal signifying the detected result is generated, and the generated detection signal is output;
the comparator includes one inverting input terminal and two non-inverting input terminals;
the predetermined reference voltage is input to the inverting input terminal;
an input detection voltage proportional to the input voltage is input to one of the two non-inverting input terminals;
a temperature detection voltage corresponding to the ambient temperature is input to the other of the two non-inverting input terminal; and
when the input voltage is a first predetermined value or more and the ambient temperature is a second predetermined value or less,
the comparator generates the predetermined detection signal and outputs the generated detection signal.

13. The electronic apparatus as claimed in claim 12, wherein:
the comparator includes a differential amplifier circuit; and the differential amplifier circuit includes
a first input transistor whose control electrode is the inverting input terminal;
a second input transistor whose control electrode is one of the non-inverting input terminals;
a third input transistor whose control electrode is the other of the non-inverting input terminals;
a constant current source which supplies a predetermined constant current to the first through third input transistors; and
a current mirror circuit which is a load on the first through third input transistors; wherein
the current mirror circuit controls so that a current proportional to a current flowing into the first input transistor flows into the second and third input transistors; and
a connection point of the second and third input transistors with the current mirror circuit is an output terminal of the differential amplifier circuit.

14. An electronic apparatus, comprising:
a detecting circuit which detects whether a plurality of conditions are satisfied, generates a predetermined detection signal signifying the detected result, and outputs the generated detection signal; and
one or more functional circuits having corresponding functions which circuits are operated based on the detection signal; wherein
the detecting circuit includes
a comparator having one non-inverting input terminal and a plurality of inverting input terminals; and
a predetermined reference voltage is input to the non-inverting input terminal of the comparator, and corresponding voltages for detecting the plural conditions are input to the corresponding inverting input terminals of the comparator; and
the comparator generates the predetermined detection signal and outputs the generated detection signal when the plural conditions are satisfied.

15. The electronic apparatus as claimed in claim 14, wherein:
when an input voltage and an ambient temperature are detected as the plural conditions, the predetermined detection signal signifying the detected result is generated, and the generated detection signal is output;
the comparator includes one non-inverting input terminal and two inverting input terminals;
the predetermined reference voltage is input to the non-inverting input terminal;
an input detection voltage proportional to the input voltage is input to one of the two inverting input terminals;
a temperature detection voltage corresponding to the ambient temperature is input to the other of the two inverting input terminal; and
when the input voltage is a first predetermined value or more and the ambient temperature is a second predetermined value or less,
the comparator generates the predetermined detection signal and outputs the generated detection signal.

16. The electronic apparatus as claimed in claim 15, wherein:
the comparator includes a differential amplifier circuit; and the differential amplifier circuit includes
a first input transistor whose control electrode is the non-inverting input terminal;
a second input transistor whose control electrode is one of the inverting input terminals;
a third input transistor whose control electrode is the other of the inverting input terminals;
a constant current source which supplies a predetermined constant current to the first through third input transistors; and
a current mirror circuit which is a load on the first through third input transistors; wherein
the current mirror circuit controls so that a current proportional to the sum of currents flowing into the first and second input transistors flows into the third input transistor; and
a connection point of the first input transistor with the current mirror circuit is an output terminal of the differential amplifier circuit.

17. The electronic apparatus as claimed in claim 12, wherein:
the detecting circuit further includes
an input detection voltage generating circuit which generates the input detection voltage by dividing the input voltage with a predetermined dividing ratio; and
a temperature detection voltage generating circuit which detects the ambient temperature, generates the temperature detection voltage corresponding to the detected ambient temperature, and outputs the generated temperature detection voltage; wherein
the temperature detection voltage generating circuit includes
a constant current source which generates a predetermined constant current and outputs the generated constant current; and
a bipolar diode to which the constant current is supplied from the constant current source; wherein
the forward voltage of the bipolar diode is the temperature detection voltage.

18. The electronic apparatus as claimed in claim 15, wherein:
the detecting circuit further includes
an input detection voltage generating circuit which generates the input detection voltage by dividing the input voltage with a predetermined dividing ratio; and
a temperature detection voltage generating circuit which detects the ambient temperature, generates the temperature detection voltage corresponding to the detected ambient temperature, and outputs the generated temperature detection voltage; wherein
the temperature detection voltage generating circuit includes
a constant current source which generates a predetermined constant current and outputs the generated constant current; and
a bipolar diode to which the constant current is supplied from the constant current source; wherein
the forward voltage of the bipolar diode is the temperature detection voltage.

19. The electronic apparatus as claimed in claim 11, further comprising:
a control circuit which controls operations of the functional circuits based on the detection signal from the detecting circuit and an external input signal from an external device.

20. The electronic apparatus as claimed in claim 14 further comprising:
a control circuit which controls operations of the functional circuits based on the detection signal from the detecting circuit and an external input signal from an external device.
